(19) United States
(12) Patent Application Publication
(10) Pub. No.: US 2017/0222086 A1
(43) Pub. Date: Aug. 3, 2017

(54) LASER PROCESSING FOR SOLAR CELL BASE AND EMITTER REGIONS

(71) Applicant: Solexel, Inc., Milpitas, CA (US)

(72) Inventors: Heather Deshazer, Palo Alto, CA (US); Virendra V. Rana, Los Gatos, CA (US); Sean M. Seutter, San Jose, CA (US); Pawan Kapur, Burlingame, CA (US); Mehrdad M. Moslehi, Los Altos, CA (US); Solene Coutant, San Jose, CA (US)

(21) Appl. No.: 15/491,882

(22) Filed: Apr. 19, 2017

Related U.S. Application Data
(63) Continuation of application No. 14/488,263, filed on Sep. 16, 2014, now abandoned.
(60) Provisional application No. 61/878,573, filed on Sep. 16, 2013.
(60) Provisional application No. 61/898,504, filed on Nov. 1, 2013.

(51) Int. Cl. H01L 31/18; H01L 31/0224; H01L 31/0216

(52) U.S. Cl. CPC H01L 31/1864; H01L 31/1868; H01L 31/02167; H01L 31/022441

(57) ABSTRACT

The present application provides effective and efficient structures and methods for the formation of solar cell base and emitter regions using laser processing. Laser absorbent passivation materials are formed on a solar cell substrate and patterned using laser ablation to form base and emitter regions.

### CROSS-REFERENCE TO RELATED APPLICATIONS

This application is a continuation of U.S. patent application Ser. No. 14/488,263, filed Sep. 16, 2014, which claims the benefit of U.S. provisional patent applications 61/878,573 filed Sep. 16, 2013 and 61/898,504 filed Nov. 1, 2013, the entire contents of each of which is hereby incorporated by reference in their entirety.

### FIELD OF THE INVENTION

The present disclosure relates in general to the field of solar cells, and more particularly solar cell base and emitter formation.

### BACKGROUND

Achieving high cell and module efficiencies in conjunction with a low fabrication cost is critical in solar cell development and manufacturing. Effective solar cell processing and structures emphasizing manufacturability considerations such as throughput and reliability while maintaining and/or improving solar cell structural designs and processing methods are gaining increasing importance for the widespread manufacture and adoption of solar energy generation.

Solar cell base and emitter formation generally involves doping of a solar cell substrate (e.g., n type or p type) to form a pattern of base and emitter regions for corresponding contact metallization. Various known semiconductor solar cell substrate processing structures and methods exist for a combination of layer formation, doping, patterning, etc. required for solar cell base and emitter formation. These structures and methods may include for example a combination of lithography, etch, and/or diffusion, etc., processing.

However, these traditional structures and methods may suffer from fabrication complexities and challenges, particularly related to through-put, as well as challenges limiting their applicability to leading edge solar cell designs.

### BRIEF SUMMARY OF THE INVENTION

Therefore, a need has arisen for solar cell base and emitter formation that improve fabrication processes and provide increased solar cell performance. In accordance with the disclosed subject matter, for solar cell base and emitter formation methods are provided which substantially eliminates or reduces disadvantages and deficiencies associated with previously developed solar cell base and emitter formation methods.

According to one aspect of the disclosed subject matter a method for processing a solar cell is provided. A doped laser absorbent passivation layer is deposited on the surface of a solar cell. The doped laser absorbent passivation layer is patterned using laser ablation. Annealing forms diffuse solar cell doped regions corresponding to the doped laser absorbent passivation layer.

These and other aspects of the disclosed subject matter, as well as additional novel features, will be apparent from the description provided herein. The intent of this summary is not to be a comprehensive description of the claimed subject matter, but rather to provide a short overview of some of the subject matter's functionality. Other systems, methods, features and advantages here provided will become apparent to one with skill in the art upon examination of the following FIGURES and detailed description. It is intended that all such additional systems, methods, features and advantages that are included within this description, be within the scope of any claims.

### BRIEF DESCRIPTION OF THE DRAWINGS

The features, natures, and advantages of the disclosed subject matter may become more apparent from the detailed description set forth below when taken in conjunction with the drawings in which like reference numerals indicate like features and wherein:

FIGS. 1 through 3 are process flows for forming a back contact back junction solar cells in accordance with the disclosed subject matter;

FIG. 4 is a cross-sectional diagram of a back contact back junction solar cell;

FIG. 5 is a process flow for forming a front contact solar cell in accordance with the disclosed subject matter;

FIGS. 6 and 7 are MEMS photographs showing ablation patterns of aluminum oxide made using a nanosecond UV laser; and

FIG. 8 is a MEMS photographs showing ablation patterns of aluminum oxide made using a picoseconds UV laser.

### DETAILED DESCRIPTION

The following description is not to be taken in a limiting sense, but is made for the purpose of describing the general principles of the present disclosure. The scope of the present disclosure should be determined with reference to the claims. Exemplary embodiments of the present disclosure are illustrated in the drawings, like numbers being used to refer to like and corresponding parts of the various drawings. The dimensions of drawings provided are not shown to scale.

And although the present disclosure is described with reference to specific embodiments and components, such as a back contact back junction silicon solar cell, one skilled in the art could apply the principles discussed herein to other solar cell structures (such as front contact or emitter wrap through—EWT—solar cells), solar cell semiconductor materials (such as GaAs, compound III-V materials), fabrication processes (such as various annealing methods and materials), as well as passivation materials (for example silicon nitride, amorphous silicon, or other non-densified passivation materials), technical areas, and/or embodiments without undue experimentation.

The present application provides effective and efficient structures and methods for the formation of solar cell base and emitter regions using laser processing. Laser patterning processes for the fabrication of back contact and front contact crystalline silicon solar cells are provided. Laser absorbent passivation materials are formed on a solar cell surface and patterned through laser ablation to form base and emitter regions. Optimal processing conditions relate to laser ablation parameters as well as passivation material properties to minimize or otherwise eliminate laser induced damage to an underlying semiconductor layer. The laser processing methods provided for solar cell base and emitter region formation in accordance with the disclosed subject matter may be integrated and/or combined into existing solar cell fabrication flows (e.g., for dopant patterning and/or diffusion).

The laser processing methods provided herein may be integrated and/or combined with the processes and structures disclosed in U.S. patent application Ser. No. 14/265,331 filed Apr. 29, 2014 which is hereby incorporated by reference in its entirety and U.S. Pat. Pub. No. 2014/0158193 published Jun. 12, 2014 which is hereby incorporated by reference in its entirety. FIG. 36 of U.S. patent application Ser. No. 14/265,331 is a process flow to form back- junction, back-contact solar cells using n-type silicon films or wafers of various thickness (e.g., thin films in the range of 10 microns 100 microns or wafers having a standard thickness, typically 150-180 microns) and a transparent silicon oxide passivation layer provided for descriptive purposes. In this process flow the laser ablation of oxide is performed using a picoseconds laser with UV (355 nm) wavelength to ablate the transparent silicon oxide through explosion of the underlying silicon, to form patterned selective emitter (lightly doped emitter junction with heavily doped emitter contact regions), patterned base, and metallization contact openings. Silicon oxide is transparent to wavelengths as short as 355 nm (UV) so the laser beam may pass through the oxide layer and damage the underlying silicon substrate. And although, the use of ultra-short pulse length such as picoseconds, and short wavelength such as UV, as well as other laser damage mitigation measures reduces and potentially eliminates damage to the underlying silicon, often damage may still be present.

FIGS. 37A and 37B of U.S. patent application Ser. No. 14/265,331 show a cross-sectional diagram of a solar cell resulting from the flow of FIG. 36 of U.S. patent application Ser. No. 14/265,331. Laser patterning is carried out by opening up the desired amount of area for selective emitter (i.e., lightly doped emitter junctions in conjunction with heavily doped emitter contact) and selective base (i.e., lightly doped base region in conjunction with heavily doped base contact) regions. The selective emitter (SE) and selective base (SB) regions may be opened up by the laser ablation that are doped with the emitter dopant (p-type emitter such as boron-doped emitter for n-base), and base dopant (n-type base such as phosphorus-doped base for n-base), respectively. These selective emitter and selective base contacts may be continuous line patterns or discrete spot-in-spot patterns where the SE and SB openings are not overlapped and the contacts openings are aligned to be isolated within the SE and Base openings (preferably with a single contact opening per discrete base island). For example see U.S. Pat. Pub. No. 2014/0158193 incorporated by reference in its entirety. The contacts to these selective emitter and base regions may be formed by a subsequent laser ablation step, for example as outlined in the process flow of FIG. 36 of U.S. patent application Ser. No. 14/265,331.

FIGS. 38A and 38B of U.S. patent application Ser. No. 14/265,331 are photographs showing the nature of laser damage of ablating transparent silicon oxide using a Gaussian laser beam with approximately ten picoseconds pulse width and 355 nm wavelength (UV). FIG. 38A of U.S. patent application Ser. No. 14/265,331 is a photograph of an ablation spot where too high a laser fluence was used. There is extensive damage in the center of the spot due to the high power at the Gaussian peak and ripples extending towards the ablation edge. This crystalline lattice damage can be reduced by lowering the laser fluence to the minimum required for ablation. FIG. 38B U.S. patent application Ser. No. 14/265,331 is a photograph of an ablation spot using a lower laser fluence. Ripples may also be observed in the laser- ablated spots.

Laser processing using passivation layers transparent to the laser wavelength often may result in laser damage to underlying silicon. However, if the passivation layer is made absorbent to the laser beam a significant amount of laser radiation from reaching the silicon substrate may be prevented and damage free or negligible damage ablation and laser patterning may be facilitated. This may be particularly advantageous in combination with thermally robust passivation layers (i.e., able to withstand and maintain material characteristics at high temperatures which may be required for solar cell processing) such as aluminum oxide. Aluminum oxide Al₂O₃ is an advantageous material for the passivation of p and p+ type crystalline silicon surfaces in part because of its fixed negative charge. And although, crystalline aluminum oxide is transparent to light wavelength down to UV (355 nm), low temperature deposition of aluminum oxide may lead to amorphous or non-densified (i.e., non-crystalline) films. Amorphous or non-densified aluminum oxide may be formed by Al₂O₃ deposition at lower temperatures, for example at a temperature less than 450° C., for example at 380° C. Nevertheless, the absorption in certain usable wavelength ranges, for example such as UV to IR, may not be significant. Films deposited using APCVD (atmospheric pressure chemical vapor deposition) having an excess of oxygen such that the layer has a non-zero extinction coefficient and can absorb laser beam in the UV to IR (1064 nm) range (deposition factors such as temperature and deposition rate may contribute to extinction coefficient), with the absorption being higher for shorter wavelengths. Alternatively, a metal rich aluminum oxide passivation layer may also be laser absorbent in the UV to IR range.

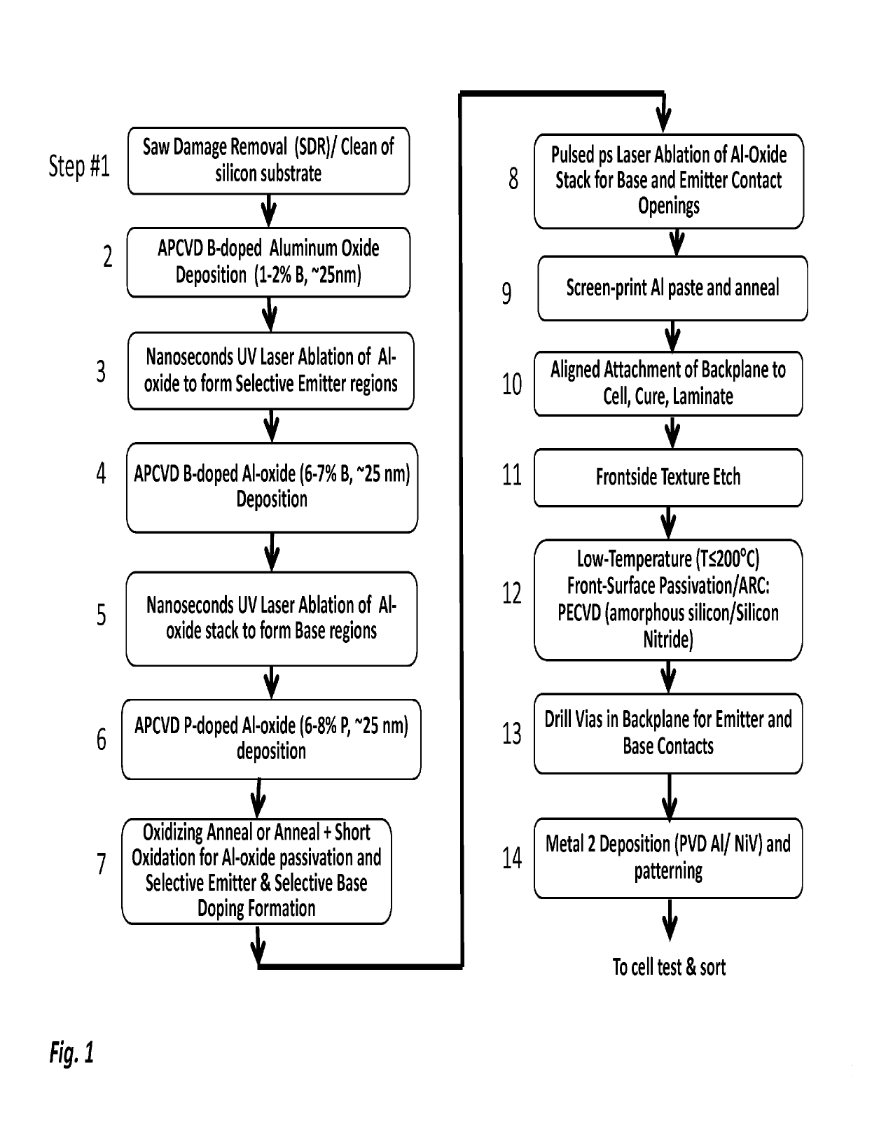

Often, for manufacturing purposes, it is desirable to minimize the thickness of these passivation films to be as thin as possible and it may be preferable to use UV wavelength laser. However, APCVD deposited amorphous silicon films with the desired excess of oxygen suitable for laser ablation typically do not provide adequate passivation to the silicon surface. Thus, subsequent to laser ablation, suitable annealing is carried out as a part of the process flow, such as that outlined in FIG. 1, to oxidize and change the film structure so that the passivation properties are maximized.

Laser processing parameters may be selected for the ablation of passivation films. For absorptive films the thickness of films removed by pulsed laser ablation may depend not only on the pulse energy and wavelength but also on the pulse length. Thicker films are removed at higher pulse energy. Since longer wavelengths penetrate deeper, depending on the thickness of the film to be removed/ablated, a suitable wavelength in the range of IR to UV can be selected. However, pulse length also has a strong effect. Nanoseconds pulse length may be advantageous in limiting damage to the underlying silicon. Picoseconds pulses may cause cold ablation where the material dissociates because of coulombic repulsion as the electrons are stripped away from the atoms. This may be more effective than the removal of material by heating and evaporation. Also, ablation using picosecond pulse length forms smaller particles because of the separation instigated by this coulombic repulsion. These particles are readily removed using an air knife and exhaust. Hence, picoseconds lasers can be advantageous in removing thicker films without the particle problem.

It should be clear to workers familiar with laser processing the selection of picoseconds or nanosecond pulses and IR, green, or UV wavelength may vary for ablating a certain thickness of an absorptive aluminum oxide film.

Generally, damage free ablation of aluminum oxide is achieved by making the film absorbent to the laser radiation used. While crystalline aluminum oxide films are transparent to the typical wavelengths used for laser ablation (UV to IR), amorphous aluminum oxide films deposited under suitable process conditions can be absorptive to these wavelengths. The laser ablation of such films under suitable conditions can lead to damage free solar cell patterning processes since the laser energy is prevented from damaging the underlying silicon substrate.

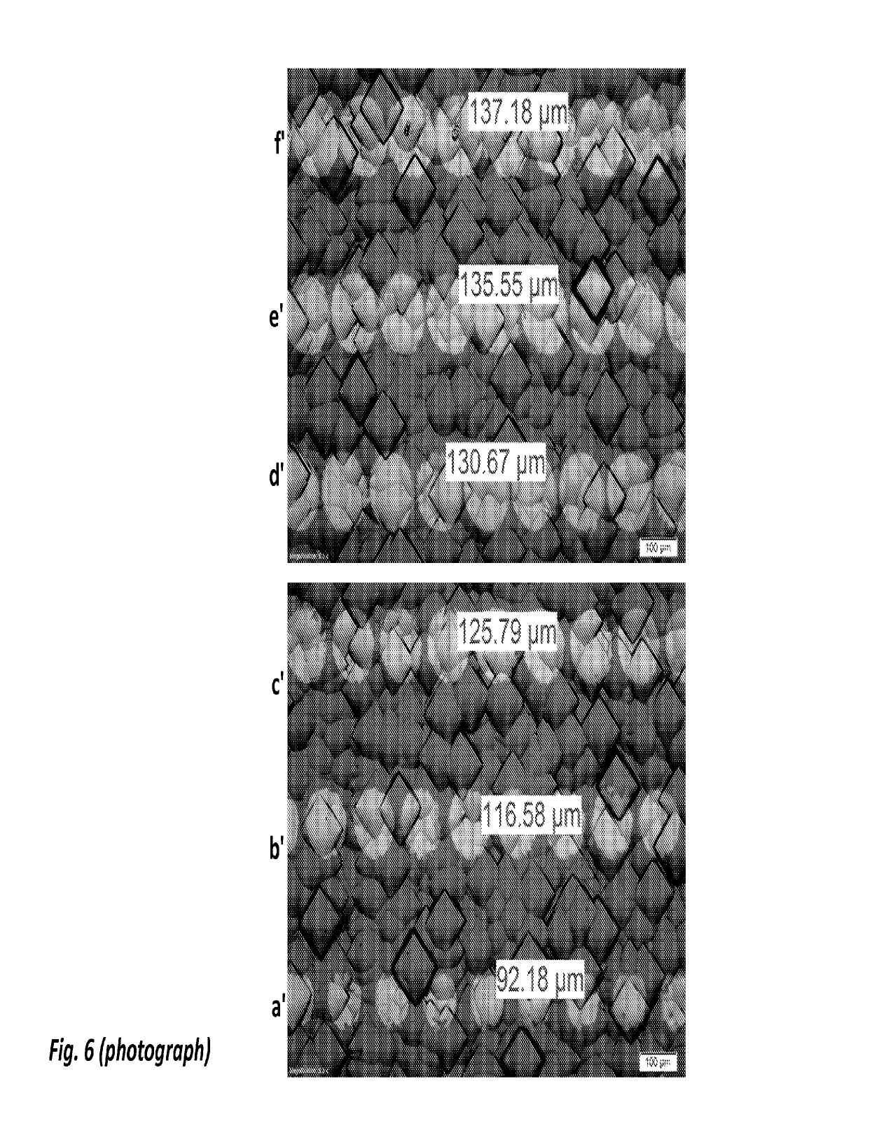

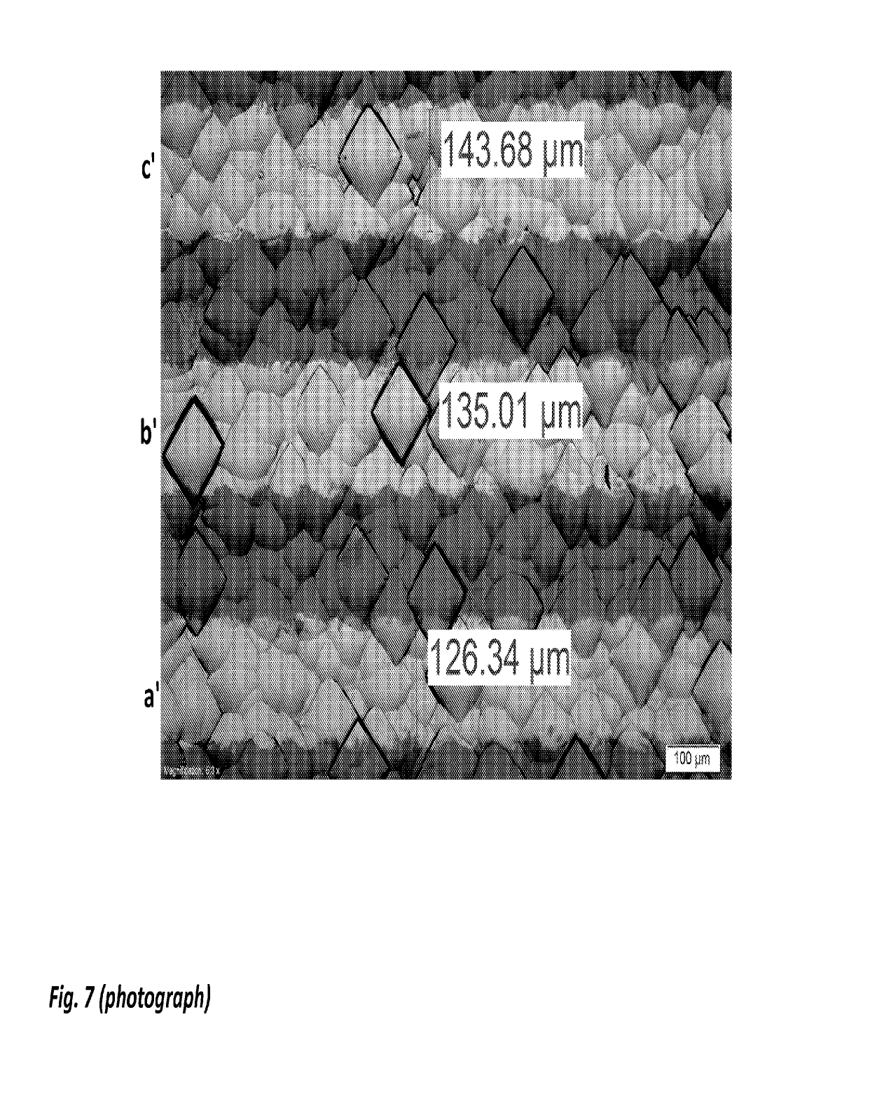

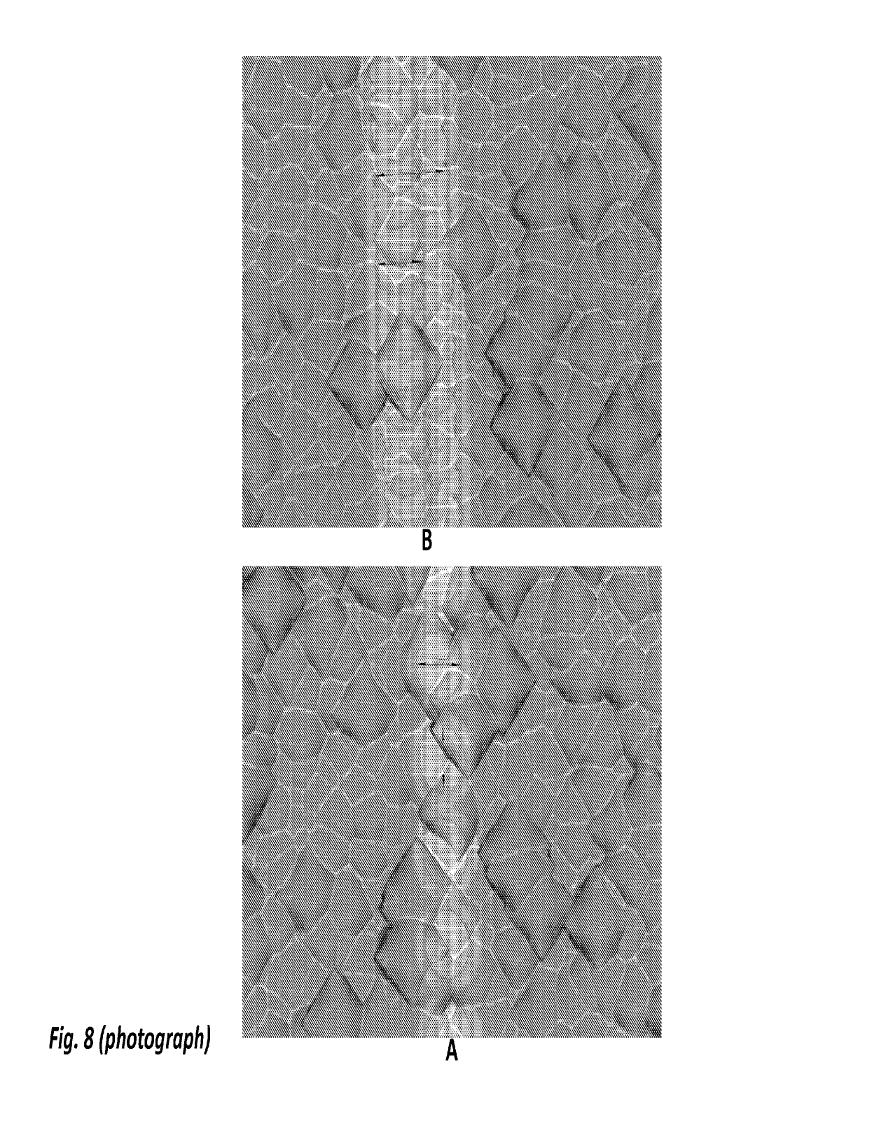

FIGS. 6 and 7 are MEMS photographs showing ablation patterns of aluminum oxide made using a nanosecond UV laser under various conditions. FIG. 8 is a MEMS photographs showing ablation patterns of aluminum oxide made using a picoseconds UV laser. In a specific instance, laser parameter selection for ablation of absorptive aluminum oxide films, which may partially depend on aluminum oxide thickness, may include nanoseconds UV laser having a pulse width in the range of 1 to 100 nanoseconds and in some instances 1 to 30 nanoseconds. For example, in some instances for an aluminum oxide film having a thickness in the range of 40 to 60 nm and an undoped silicon oxide cap a UV laser having a pulse width of 30 nanoseconds may be used.

The flow of FIG. 1 is consistent with the process flow of FIG. 36 in U.S. patent application Ser. No. 14/265,331 filed Apr. 29, 2014 incorporated by reference in its entirety. FIG. 1 is a process flow for forming a back contact back junction solar cell starting with an n-type silicon where laser absorbent, doped aluminum oxide is substituted for the silicon oxide of FIG. 36 in U.S. patent application Ser. No. 14/265,331 to obtain laser damage free emitter and base patterning. Thin layers of aluminum oxide (e.g., preferably very thin layers having a thickness greater than 5 microns and in some instances in the range of 10 to 50 nm) may be used for throughput and cost reasons. Thicker films of Al₂O₃ may also be used which can also facilitate the use of higher wavelengths such as green or IR. Optionally, if required, undoped aluminum oxide cap layers may be used to facilitate integration with existing solar cell fabrication flows and particularly to prevent the evaporation loss of dopants, dopant intermixing, and penetration of thinner aluminum oxide films by metal. Capping layers include materials such as undoped aluminum oxide and undoped silicon oxide which may, for example, have a thickness in the range of 100 to 600 nm. The process flow shown in FIG. 1 may be used on thin films of silicon having a thickness as thin as approximately 10 microns and as thick as approximately 100 microns.

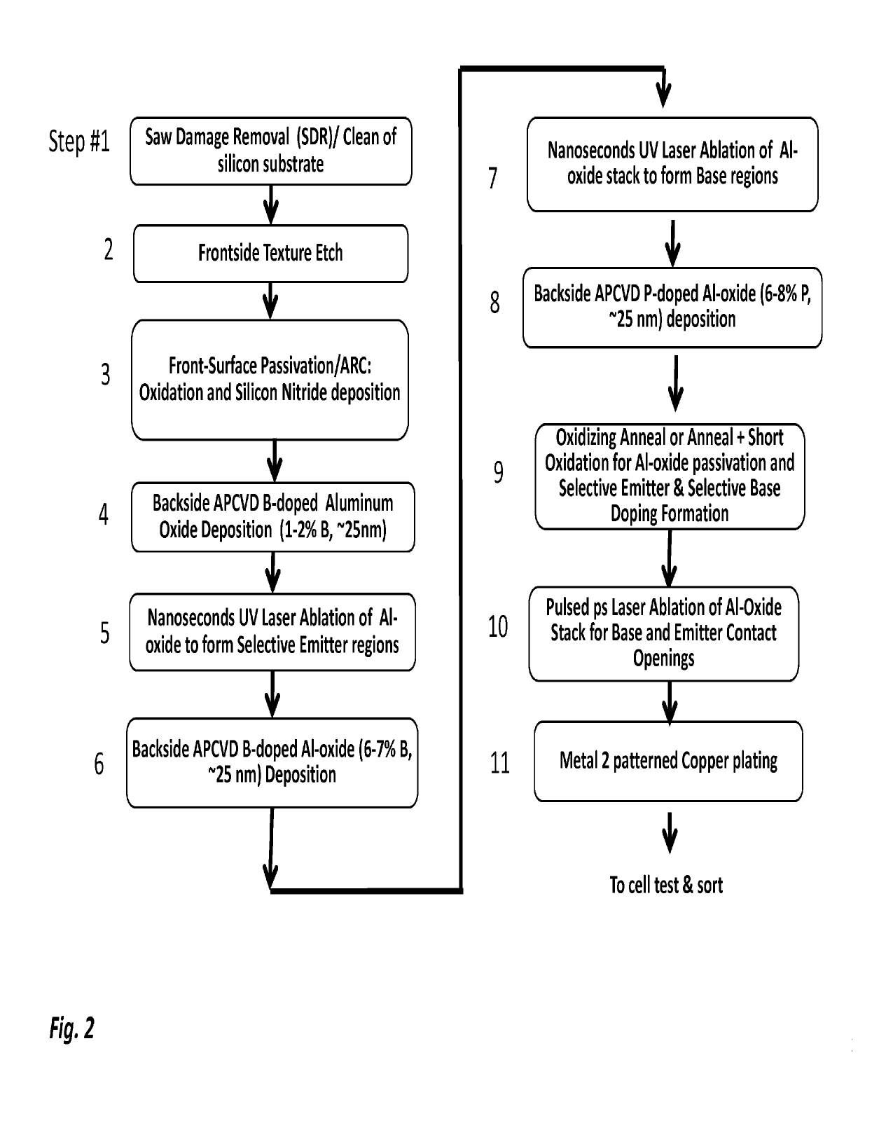

FIG. 2 is a process flow for forming a back contact back junction solar cell starting with an n-type silicon using laser absorbent doped aluminum oxide suitable on a thicker starting wafer (for example having a thickness in the range of approximately 100 to 200 microns) as compared to the starting wafer of FIG. 1. Note a supporting backplane is not used in the flow of FIG. 2.

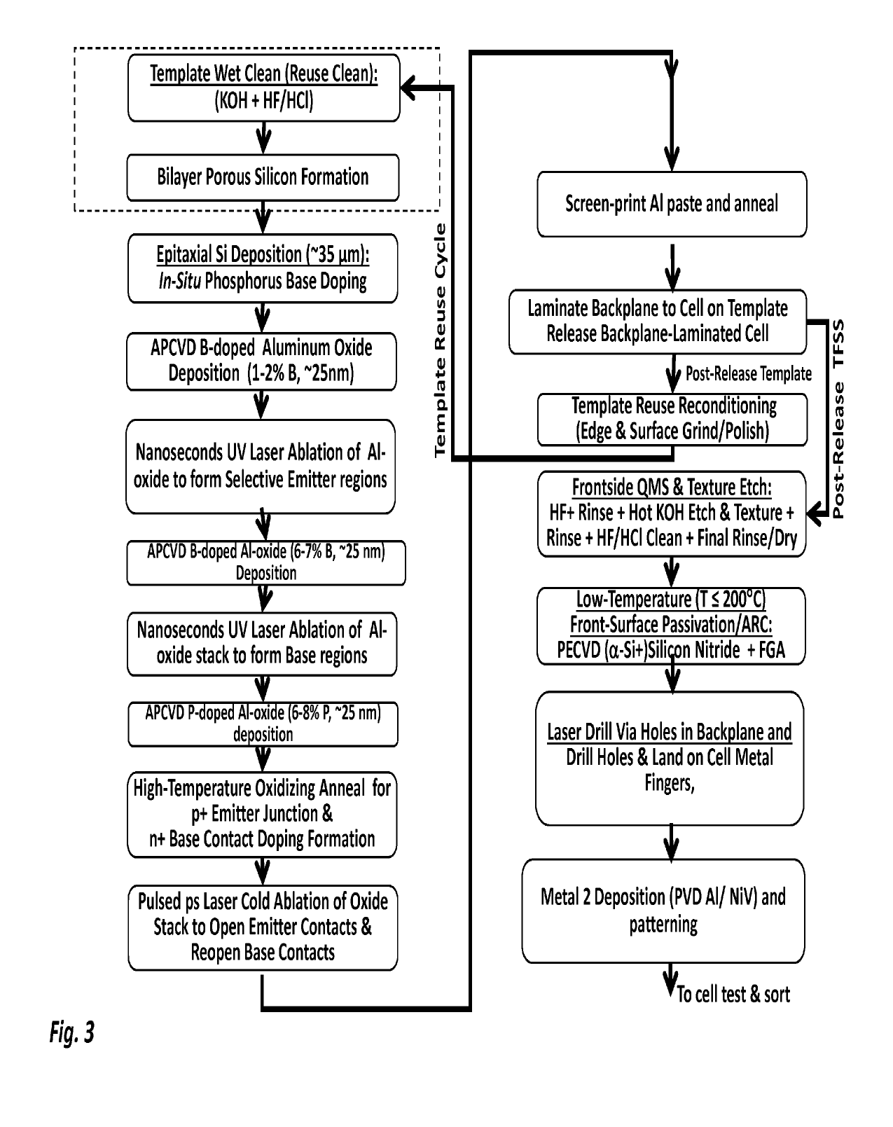

FIG. 3 is a process flow for forming a back contact back junction solar cell using a starting thin silicon film formed via an epitaxial deposition on porous silicon lift-off process.

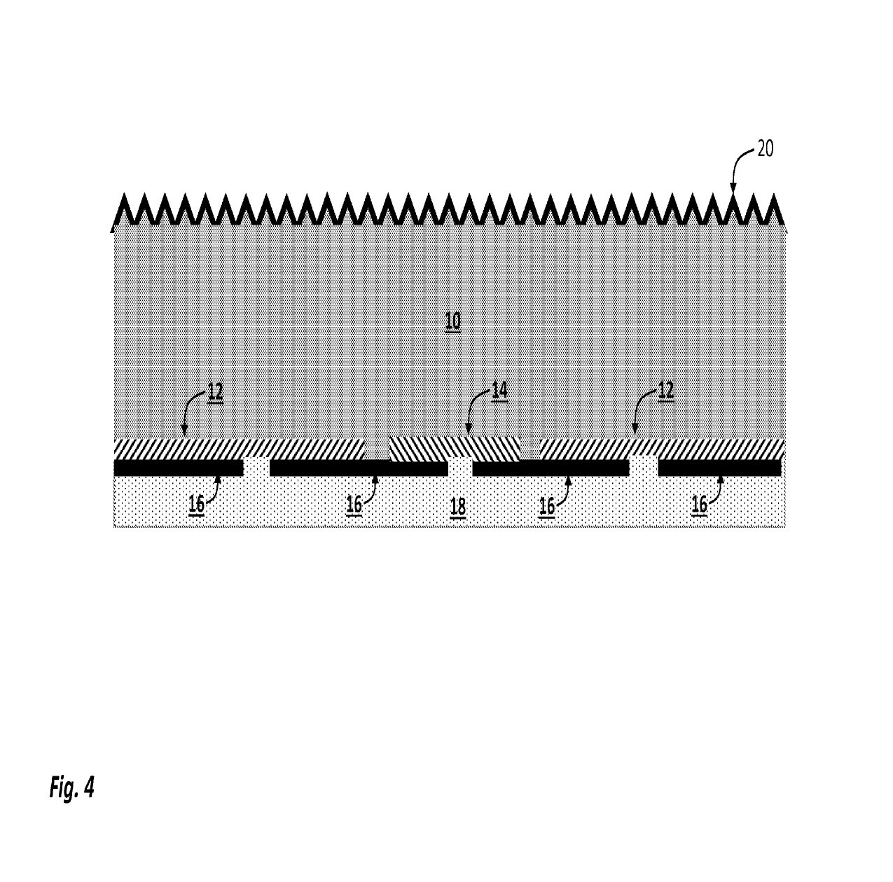

FIG. 4 is a cross-sectional diagram of a resulting back contact back junction solar cell formed according to the back contact back junction solar cell process flows provided herein. A Textured solar cell frontside 20 (for example coated with an amorphous silicon/PECVD nitride layer) is on the front/light receiving side of silicon solar cell substrate 10 (for example having n-type base). P+ emitter regions 12 and n++ base regions 14 are contacted to metallization layer 18 (for example an aluminum/nickel vanadium/tin stack) through aluminum oxide passivation layer 16 (for example an aluminum oxide stack).

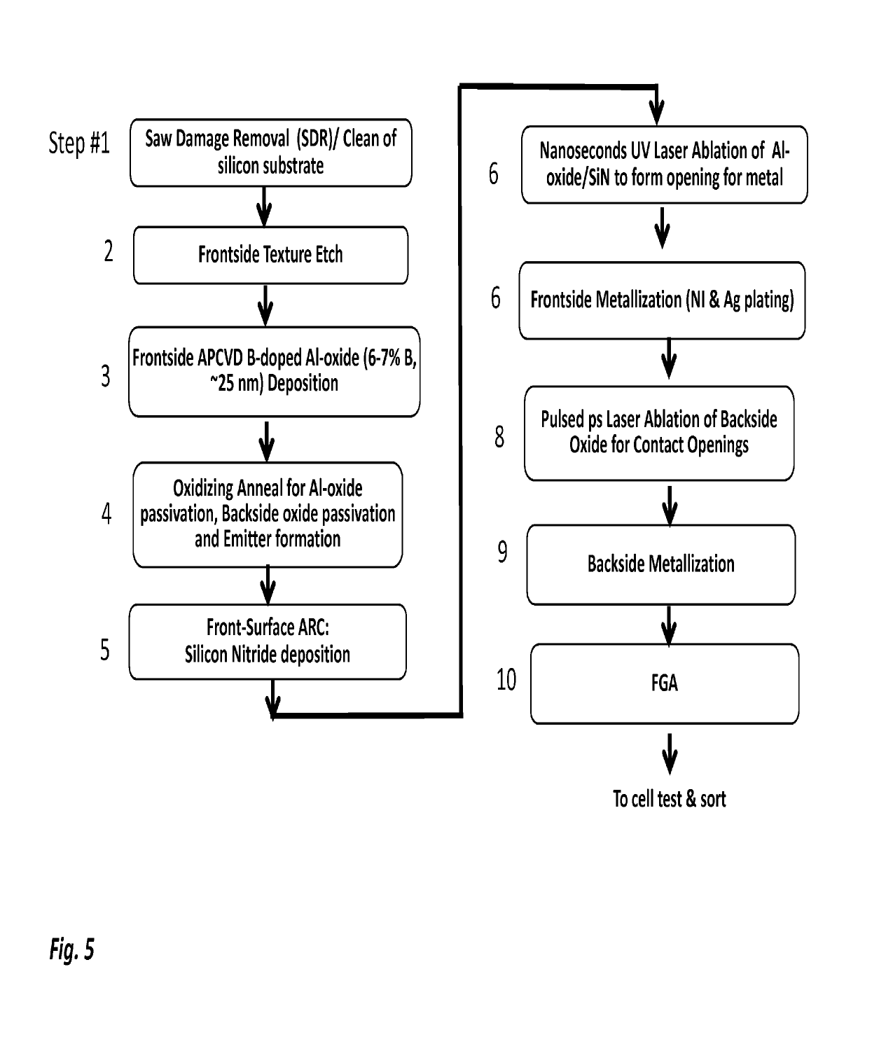

FIG. 5 is a process flow for forming a front contact solar cell starting with an n-type silicon wafer. Laser absorbent aluminum oxide is used to define a fine line metallization pattern.

FIGS. 6 and 7 are MEMS photographs showing ablation patterns of aluminum oxide made using a nanosecond UV laser under various conditions. FIG. 6 is a photograph showing ablation spots formed in aluminum oxide using a 30 nanosecond, UV laser with pulse energies (in micro-joules) of: a′=52, b′=95, c′=141, d′=183, e′=216, and P=234. FIG. 7 is a photograph showing ablation scribes (lines) formed in aluminum oxide using a 30 nanosecond, UV laser with laser fluences (in J/cm²) of: a′=0.6, b′=00.7, and c′=0.74.

FIG. 8 is a MEMS photographs showing ablation patterns of aluminum oxide made using a picoseconds UV laser. FIG. 8 is a photograph showing ablation scribes formed in aluminum oxide using a 12 picosecond, UV laser with FIG. 8 photograph A showing isolated spot patterning and FIG. 8 photograph B showing continuous line patterning.

The foregoing description of the exemplary embodiments is provided to enable any person skilled in the art to make or use the claimed subject matter. Various modifications to these embodiments will be readily apparent to those skilled in the art, and the generic principles defined herein may be applied to other embodiments without the use of the innovative faculty. Thus, the claimed subject matter is not intended to be limited to the embodiments shown herein but is to be accorded the widest scope consistent with the principles and novel features disclosed herein.

What is claimed is:

1. A method for making a solar cell, comprising:
depositing a doped laser absorbent passivation layer on the surface of a solar cell substrate, said doped laser absorbent passivation layer having a doping opposite said solar cell substrate;
patterning said doped laser absorbent passivation layer using laser ablation; and
annealing said solar cell to form diffused solar cell doped regions corresponding to said doped laser absorbent passivation layer.

2. The method of claim 1, wherein said doped laser absorbent passivation layer is an oxygen rich doped laser absorbent passivation layer.

3. The method of claim 1, wherein said doped laser absorbent passivation layer is an metal rich doped laser absorbent passivation layer.

4. The method of claim 1, wherein said doped laser absorbent passivation layer is aluminum oxide.

5. The method of claim 4, wherein said doped laser absorbent passivation aluminum oxide layer has a thickness in the range of 10 to 50 nm.

6. The method of claim 1, wherein said laser ablation has a wavelength in the IR to UV range.

7. The method of claim 1, wherein said laser ablation has a pulse width in the range of 1 to 100 nanoseconds.

8. A method for making a solar cell, comprising:
depositing a first doped oxygen rich non-densified aluminum oxide layer on an n-type backside surface of a solar cell substrate, said first doped oxygen rich non-densified aluminum oxide layer having a doping opposite said n-type surface of said solar cell substrate;
patterning said first doped oxygen rich non-densified aluminum oxide layer using laser ablation to define field emitter regions;
depositing a second doped oxygen rich non-densified aluminum oxide layer on said n-type backside surface of a solar cell substrate, said second doped oxygen rich non-densified aluminum oxide layer having a doping opposite said n-type surface of said solar cell substrate;
patterning said second doped oxygen rich non-densified aluminum oxide layer using laser ablation to define selective emitter regions;
depositing a third doped oxygen rich non-densified aluminum oxide layer on said n-type backside surface of a solar cell substrate, said third doped oxygen rich non-densified aluminum oxide layer having a doping the same as said n-type surface of said solar cell substrate;
laser ablating said third doped oxygen rich non-densified aluminum oxide layer to form base regions; and
annealing said solar cell substrate to form base and emitter regions of said solar cell.

9. The method of claim 8, wherein said deposition of said first doped oxygen rich non-densified aluminum oxide and said second doped oxygen rich non-densified aluminum oxide is performed by an atmospheric pressure chemical vapor deposition process.

10. The method of claim 8, wherein said laser ablation has a wavelength in the IR to UV range.

11. The method of claim 8, wherein said laser ablation has a pulse width in the range of 1 to 100 nanoseconds.

12. The method of claim 8, wherein said first doped oxygen rich non-densified aluminum oxide layer and said second oxygen rich non-densified aluminum oxide layer are boron doped and said third doped oxygen rich non-densified aluminum oxide layer is phosphorus doped.

13. A method for making a solar cell, comprising:
depositing a first doped oxygen rich non-densified aluminum oxide layer on an n-type backside surface of a solar cell substrate, said first doped oxygen rich non-densified aluminum oxide layer having a doping opposite said n-type surface of said solar cell substrate;
patterning said first doped oxygen rich non-densified aluminum oxide layer using laser ablation to define field emitter regions;
depositing a second doped oxygen rich non-densified aluminum oxide layer on said n-type backside surface of a solar cell substrate, said second doped oxygen rich non-densified aluminum oxide layer having a doping the same as said n-type surface of said solar cell substrate;
laser ablating said second doped oxygen rich non-densified aluminum oxide layer to form base regions; and
annealing said solar cell substrate to form base and emitter regions of said solar cell.

14. The method of claim 13, wherein said deposition of said first doped oxygen rich non-densified aluminum oxide and said second doped oxygen rich non-densified aluminum oxide is performed by an atmospheric pressure chemical vapor deposition process.

15. The method of claim 13, wherein said laser ablation has a wavelength in the IR to UV range.

16. The method of claim 13, wherein said laser ablation has a pulse width in the range of 1 to 100 nanoseconds.
